(19) United States
(12) Patent Application Publication
(10) Pub. No.: US 2010/0040986 A1
(43) Pub. Date: Feb. 18, 2010

(54) PROCESS FOR MANUFACTURING LIGHT GUIDE

(76) Inventors: Masatoshi Yamaguchi, Ibaraki (JP); Tomoaki Shibata, Ibaraki (JP); Tatsuya Makino, Ibaraki (JP); Masami Ochiai, Ibaraki (JP); Toshihiko Takasaki, Ibaraki (JP); Atsushi Takahashi, Ibaraki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/440,517

(22) PCT Filed: Sep. 18, 2007
(86) PCT No.: PCT/JP2007/068049

§ 371 Date: Mar. 9, 2009

(30) Foreign Application Priority Data
Sep. 22, 2006 (JP) 2006-257350
Nov. 17, 2006 (JP) 2006-312033

(51) Int. Cl. G03F 7/20

(52) U.S. Cl. 430/321

(57) ABSTRACT

The present invention relates to a process for producing an optical waveguide, including the steps of applying a cladding layer-forming resin onto a substrate and curing the resin to form a lower cladding layer; laminating a core layer-forming resin film on the lower cladding layer to form a core layer; subjecting the core layer to exposure to light and development to form a core pattern; and applying a cladding layer-forming resin over the core pattern to embed the core pattern therebeneath, and curing the resin to form an upper cladding layer, wherein the step of forming the core layer includes the steps of (1) allowing the core layer-forming resin film to be temporarily attached onto the lower cladding layer using a roll laminator, and (2) thermocompression-bonding the temporarily attached core layer-forming resin film onto the lower cladding layer under a reduced pressure. There is provided the process for producing an optical waveguide having a uniform core with a good productivity.

### TECHNICAL FIELD

The present invention relates to a process for producing optical waveguides having a uniform core with an excellent productivity.

### BACKGROUND ART

With the increase in information capacity, in various applications including not only telecommunication applications such as trunk lines and access systems but also information processing within routers and servers, development of optical interconnection techniques using optical signal have proceeded. More specifically, since light is used for short-distance signal transmission between or within boards in the routers or servers, an optical-electrical composite board on which an electric wiring board and an optical transmission line are mounted in a combined manner has been developed. As the optical transmission line, an optical waveguide is preferably used because it has a larger freedom of wiring and a capability of higher densification as compared to optical fibers. In particular, those optical waveguides produced from polymeric materials having excellent processability and economical advantages are more promising.

The optical waveguides to be disposed together with the electric wiring boards are required to have not only a high transparency but also a high heat resistance. As the materials of such optical waveguides, there have been proposed fluorinated polyimides (for example, refer to Non-Patent Document 1) and epoxy resins (for example, refer to Patent Document 1).

The fluorinated polyimides have a high heat resistance of 300° C. or higher and a high transparency of 0.3 dB/cm as measured at a wavelength of 850 nm. However, upon forming the fluorinated polyimides into a film, it is required to heat the polyimides at a temperature of 300° C. or higher for a period of from several tens minutes to several hours, thereby causing difficulty in forming the film on the electric wiring boards. In addition, since the fluorinated polyimides have no photosensitivity, methods such as exposure to light and development are not applicable upon producing an optical waveguide therefrom, resulting in poor productivity and failing to obtain the optical waveguide having a large area. Further, the optical waveguide in the form of a film must be produced by applying the resins as a liquid material onto the substrate, so that control of a thickness of the film becomes complicated. Besides, the resins applied onto the substrate are kept in a fluidized state before being cured, and therefore readily caused to flow on the substrate, thereby making it difficult to form a film having a uniform thickness. Thus, the fluorinated polyimides have problems due to the liquid material.

On the other hand, the epoxy resins for optical waveguides which are prepared by adding a photopolymerization initiator to a liquid epoxy resin are capable of forming a core pattern by using the methods such as exposure to light and development, and exhibit a high transparency and a high heat resistance. However, the epoxy resins have the same problems due to the liquid material as encountered in the fluorinated polyimides.

To solve the above problems, it is effective to use such a method for producing an optical waveguide having excellent transmission characteristics in which a dry film containing a radiation-polymerizable component is laminated on a substrate and irradiated with a given amount of light to cure a desired portion of the film and thereby form a clad, followed, if required, by developing a non-exposed portion of the film to form a core portion, and then an additional clad is formed over the core pattern to embed the core portion therebeneath. This method readily ensures a good flatness of the clad after embedding the core portion therebeneath, and is also suitable for producing an optical waveguide having a large area. As the method of laminating the dry film on the substrate, there is known a so-called vacuum lamination method in which the film is laminated under reduced pressure using a vacuum-type laminator with a vacuum chamber which is constituted from a pair of blocks capable of relative movement to each other in the up-down direction, as described in FIGS. 1 and 2 of Patent Document 2. However, when the vacuum chamber is evacuated (vacuum-drawn), air is flowed through the vacuum chamber, so that surrounding dirt, dusts, etc., are scattered around, thereby causing such a problem that the dirt, dusts, etc., tend to be deposited between the dry film and the substrate before laminated. In addition, in the vacuum lamination method, the film tends to suffer from occurrence of wrinkles upon the lamination, so that a deformed core such as a thick or lacking core tends to be caused owing to the wrinkles upon forming the core of the optical waveguide, resulting in problems such as large transmission loss of optical signals owing to scattering of light at the deformed portions of the core.

Patent Document 1: JP 6-228274A

Patent Document 2: JP11-320682A

Non-Patent Document 1: “Journal of Japan Institute of Electronics Packaging”, Vol. 7, No. 3, pp. 213-218, 2004

### DISCLOSURE OF THE INVENTION

The present invention has been made in view of the above conventional problems, and an object of the present invention is to provide a process for producing an optical waveguide having a uniform core with a good productivity.

As the result of extensive and intensive researches, the present inventors have found that the above problems can be solved by the following process of the present invention.

Thus, the present invention relates to the following aspects [1] to [4].

[1] A process for producing an optical waveguide, comprising the steps of:

applying a cladding layer-forming resin onto a substrate and curing the resin to form a lower cladding layer;

laminating a core layer-forming resin film on the lower cladding layer to form a core layer;

subjecting the core layer to exposure to light and development to form a core pattern; and

applying a cladding layer-forming resin over the core pattern to embed the core pattern therebeneath, and curing the resin to form an upper cladding layer,

wherein the step of forming the core layer comprises the steps of (1) allowing the core layer-forming resin film to be temporarily attached onto the lower cladding layer using a roll laminator, and (2) thermocompression-bonding the temporarily attached core layer-forming resin film onto the lower cladding layer under a reduced pressure.

[2] The process as described in the above aspect [1], wherein in the step (1), the core layer-forming resin film is thermocompression-bonded onto the lower cladding layer using a laminator with a heated roll as the roll laminator to temporarily attach the film thereonto.

[3] The process as described in the above aspect [1] or [2], wherein in the step (2), the core layer-forming resin film thus temporarily attached in the step (1) is thermocompression-bonded onto the lower cladding layer under reduced pressure using a flat plate-type laminator.

[4] The process as described in any one of the above aspects [1] to [3], wherein the lower cladding layer has no stepped portion on its surface on which the core layer is to be laminated.

In accordance with the present invention, the optical waveguide having a uniform core can be produced with a good productivity.

### BRIEF DESCRIPTION OF THE DRAWINGS

FIG. 1 is an explanatory view showing a process for producing an optical waveguide according to the present invention in which a support film for a cladding layer-forming resin film is used as a substrate.

FIG. 2 is an explanatory view showing a process for producing an optical waveguide according to the present invention in which a cladding layer-forming resin is applied onto another substrate that is provided separately from a support film for a cladding layer-forming resin film.

FIG. 3 is an explanatory view showing a cladding layer-forming resin film used in a process for producing an optical waveguide according to the present invention.

FIG. 4 is an explanatory view showing a core layer-forming resin film used in a process for producing a flexible optical waveguide according to the present invention.

### EXPLANATION OF REFERENCE NUMERALS

1: Substrate; 2: Lower cladding layer; 3: Core layer; 4: Support film (for forming the core layer); 5: Roll laminator; 6: Vacuum pressure laminator; 7: Photomask; 8: Core pattern; 9: Upper cladding layer; 10: Support film (for forming the cladding layer); 11: Protective film (protective layer); 20: Cladding layer-forming resin; 30: Core layer-forming resin; 200: Cladding layer-forming resin film; 300: Core layer-forming resin film

### BEST MODE FOR CARRYING OUT THE INVENTION

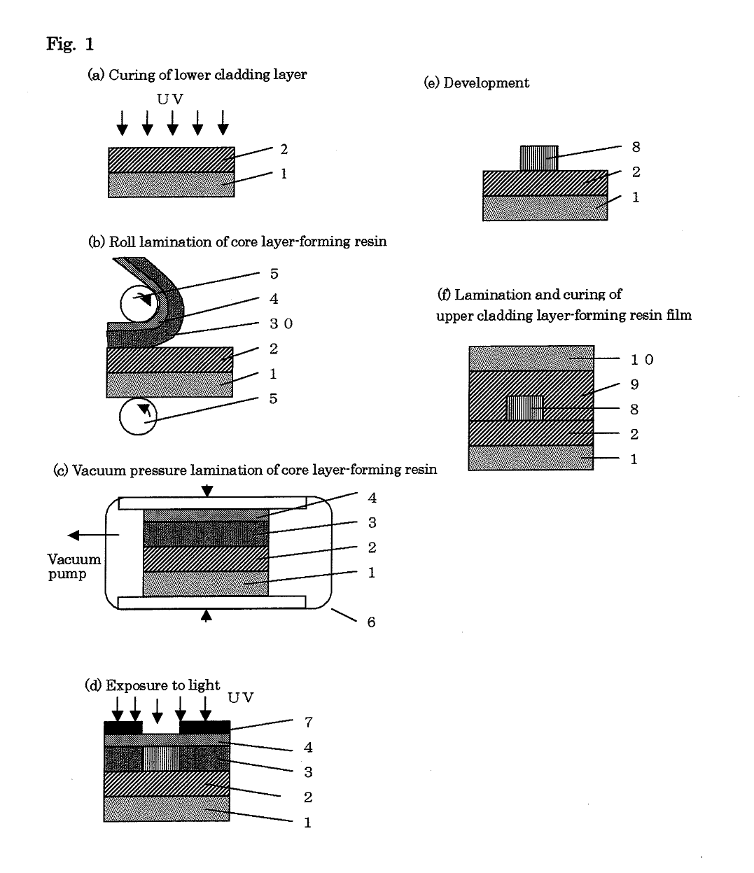

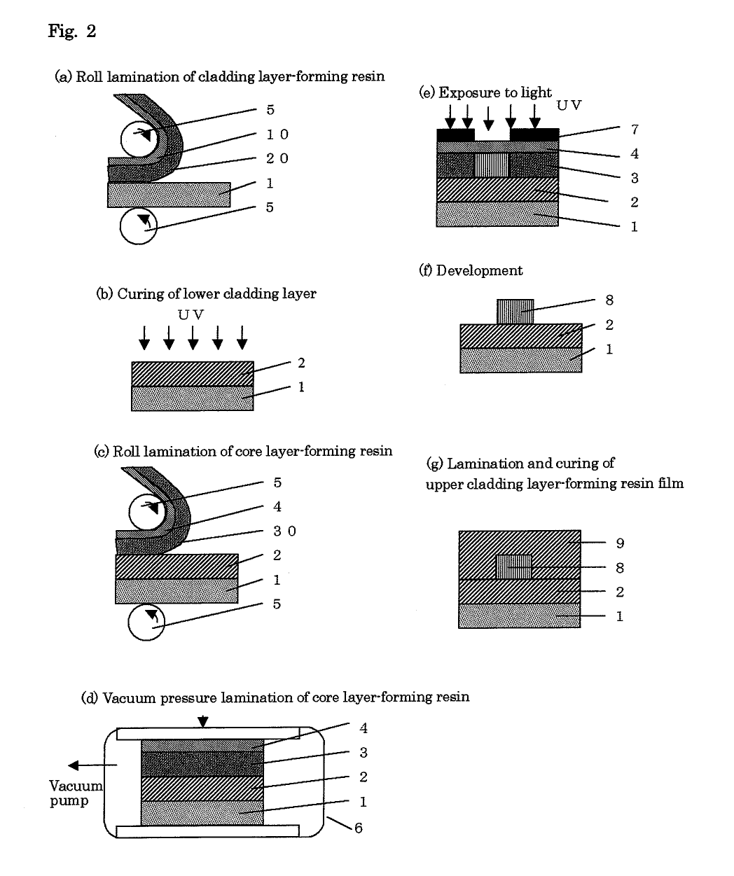

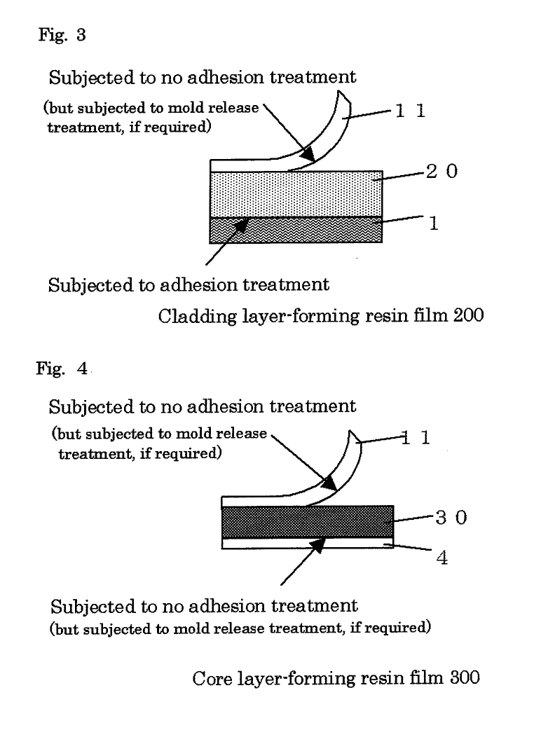

The optical waveguide produced by the process of the present invention includes, for example, a substrate 1, and a lower cladding layer 2, a core pattern 8 and an upper cladding layer 9 successively formed on the substrate, as shown in FIG. 1(f) and FIG. 2(g). The optical waveguide is produced by using one core layer-forming resin film (300 in FIG. 4) having a high refractive index, and two cladding layer-forming resins, preferably cladding layer-forming resin films (200 in FIG. 3) each having a low refractive index. By using these film materials, the problems concerning the productivity and the increase in an area of the optical waveguide which are peculiar to the liquid material can be solved.

### (Substrate)

The kind of the substrate 1 is not particularly limited. Examples of the substrate 1 include a FR-4 substrate, a polyimide substrate, a semiconductor substrate, a silicon substrate and a glass substrate.

Also, when using a film as the substrate 1, it is possible to impart a good flexibility and a high toughness to the resulting optical waveguide. The material of the film is not particularly limited. From the viewpoints of a good flexibility and a high toughness of the optical waveguide, as the film material, there may be suitably used polyesters such as polyethylene terephthalate, polybutylene terephthalate and polyethylene naphthalate; polyethylene; polypropylene; polyamides; polycarbonates; polyphenylene ethers; polyether sulfides; polyarylates; liquid crystal polymers; polysulfones; polyether sulfones; polyether ether ketones; polyether imides; polyamide imides; and polyimides.

The thickness of the film used as the substrate may appropriately vary depending upon the aimed flexibility of the optical waveguide, and is preferably from 5 to 250 μm. When the thickness of the film is 5 μm or larger, the resulting optical waveguide tends to exhibit a high toughness, whereas when the thickness of the film is 250 μm or smaller, the resulting optical waveguide tends to exhibit a sufficient flexibility.

As the substrate 1 shown in FIG. 1, there may be used a support film 10 used in the below-mentioned process for producing a cladding layer-forming resin film 200. In such a case, the cladding layer-forming resin film 200 is preferably constituted from the support film 10 subjected to adhesion treatment and a film of a cladding layer-forming resin 20 formed on the support film 10, as shown in FIG. 3. By using the support film 10 as the substrate 1, the adhesion between the lower cladding layer 2 and the substrate 1 is enhanced, thereby preventing occurrence of defective delamination between the lower cladding layer 2 and the substrate 1. The adhesion treatment as used herein means such a treatment in which the adhesion between the support film 10 and the cladding layer-forming resin 20 applied thereonto is enhanced by subjecting the support film to coating with an adhesive resin, corona treatment, matt finish such as sandblasting, etc.

When another substrate provided separately from the support film 10 is used as the substrate 1, the cladding layer-forming resin film 200 constituted from the support film 10 and a film of the cladding layer-forming resin 20 formed on the support film 10 may be transferred onto the substrate 1 by a laminating method, etc., as shown in FIG. 2. In this case, the support film 10 is preferably subjected to no adhesion treatment.

Also, an additional substrate may be provided outside of the upper cladding layer. Examples of the additional substrate include those substrates as described above for the substrate 1. For example, as shown in FIG. 1(f), the support film 10 used in the below-mentioned process for producing the cladding layer-forming resin film 200, etc., may be used as the additional substrate.

The optical waveguide of the present invention may be in the form of a multilayer optical waveguide in which a plurality of polymer layers each including a core pattern and a cladding layer are laminated on one or both surfaces of the substrate 1.

Further, an electric wiring pattern may be provided on the above substrate 1. In this case, a substrate on which the electric wiring pattern is previously formed may be used as the substrate 1. Alternatively, the electric wiring pattern may be formed on the substrate 1 after production of the optical waveguide. The thus produced optical waveguide is provided on the substrate 1 with both of a signal transmission line constructed by the metal wiring and a signal transmission line constructed by the optical waveguide which may be selectively used according to the requirements, thereby enabling long-distance signal transmission at a high speed.

### (Cladding Layer-Forming Resin and Cladding Layer-Forming Resin Film)

In the followings, the cladding layer-forming resin and the cladding layer-forming resin film (200 in FIG. 3) used in the present invention are described in detail.

The cladding layer-forming resin used in the present invention is not particularly limited as long as it is in the form of a resin composition capable of exhibiting a lower refractive index than that of the core layer and being cured upon exposure to light or heat. As the cladding layer-forming resin, there may be suitably used a heat-curable resin composition and a photosensitive resin composition. The cladding layer-forming resin is more preferably a resin composition composed of (A) a base polymer, (B) a photopolymerizable compound and (C) a photopolymerization initiator. Meanwhile, the resin compositions used as the cladding layer-forming resins for the upper cladding layer 9 and the lower cladding layer 2 may be the same or different in components contained therein as well as refractive index thereof.

The base polymer (A) used in the resin composition serves for forming the cladding layer and ensuring strength thereof, and is not particularly limited as long as these objects can be achieved. Examples of the base polymer (A) include phenoxy resins, epoxy resins, (meth)acrylic resins, polycarbonate resins, polyarylate resins, polyether amides, polyether imides, polyether sulfones and derivatives of these polymers. These base polymers (A) may be used alone or in the form of a mixture of any two or more thereof. Among the above-mentioned base polymers, from the viewpoint of a high heat resistance, preferred are those having an aromatic skeleton in a main chain thereof, and more preferred are phenoxy resins. Also, from the viewpoint of enhancing a heat resistance owing to a three-dimensional crosslinked structure thereof, preferred are epoxy resins, and more preferred are those epoxy resins that are kept in a solid state at room temperature. Further, in order to ensure a good transparency of the cladding layer-forming resin, it is important that the base polymer exhibits a good compatibility with the below-mentioned photopolymerizable compound (B). From this viewpoint, among the base polymers, preferred are phenoxy resins and (meth)acrylic resins. Meanwhile, the “(meth)acrylic resin” as used herein means both an acrylic resin and a methacrylic resin.

Among the above phenoxy resins, those phenoxy resins containing bisphenol A, a bisphenol A-type epoxy compound or a derivative thereof, and bisphenol F, a bisphenol F-type epoxy compound or a derivative thereof as constitutional comonomer units are preferred because they are excellent in heat resistance, adhesion and dissolvability. Examples of the suitable derivative of bisphenol A or the bisphenol A-type epoxy compound include tetrabromobisphenol A and tetrabromobisphenol A-type epoxy compounds. Examples of the suitable derivative of bisphenol F or the bisphenol F-type epoxy compound include tetrabromobisphenol F and tetrabromobisphenol F-type epoxy compounds.

Specific examples of the bisphenol A/bisphenol F copolymer-type phenoxy resins include “PHENOTOHTO YP-70” (tradename) available from Tohto Kasei Co., Ltd.

Examples of the epoxy resins that are kept in a solid state at room temperature include bisphenol A-type epoxy resins such as “EPOTOHTO YD-7020”, “EPOTOHTO YD-7019” and “EPOTOHTO YD-7017” (tradenames) all available from Tohto Kasei Co., Ltd., and “EPICOAT 1010”, “EPICOAT 1009” and “EPICOAT 1008” (tradenames) all available from Japan Epoxy Resins Co., Ltd.

Next, the photopolymerizable compound (B) is not particularly limited as long as it is capable of being polymerized by irradiation with light such as ultraviolet light. Examples of the photopolymerizable compound (B) include compounds having an ethylenically unsaturated group in a molecule thereof and compounds having tow or more epoxy groups in a molecule thereof.

Examples of the compounds having an ethylenically unsaturated group in a molecule thereof include (meth)acrylates, halogenated vinylidenes, vinyl ethers, vinyl pyridine and vinyl phenol. Among these compounds, form the viewpoint of a good transparency and a good heat resistance, preferred are (meth)acrylates.

As the (meth)acrylates, there may be used any of monofunctional, bifunctional and trifunctional or more polyfunctional (meth)acrylates. Meanwhile, the “(meth)acrylate” as used herein means both of an acrylate and a methacrylate.

Examples of the compounds having two or more epoxy groups in a molecule thereof include bifunctional or polyfunctional aromatic glycidyl ethers such as bisphenol A-type epoxy resins, bifunctional or polyfunctional aliphatic glycidyl ethers such as polyethylene glycol-type epoxy resins, bifunctional alicyclic glycidyl ethers such as hydrogenated bisphenol A-type epoxy resins, bifunctional aromatic glycidyl esters such as diglycidyl phthalate, bifunctional alicyclic glycidyl esters such as diglycidyl tetrahydrophthalate, bifunctional or polyfunctional aromatic glycidyl amines such as N,N-diglycidyl aniline, bifunctional alicyclic epoxy resins such as alicyclic diepoxy carboxylates, bifunctional heterocyclic epoxy resins, polyfunctional heterocyclic epoxy resins, and bifunctional or polyfunctional silicon-containing epoxy resins. These photopolymerizable compounds (B) may be used alone or in combination of any two or more thereof.

Next, the photopolymerization initiator (C) is not particularly limited. Examples of the photopolymerization initiator (C) which may be used together with the epoxy compound as the component (B) include aryl diazonium salts, diaryl iodonium salts, triaryl sulfonium salts, triaryl selenonium salts, dialkylphenazyl sulfonium salts, dialkyl-4-hydroxyphenyl sulfonium salts and sulfonic acid esters.

Also, examples of the photopolymerization initiator (C) which may be used together with the compound having an ethylenically unsaturated group in a molecule thereof as the component (B) include aromatic ketones such as benzophenone, quinones such as 2-ethyl anthraquinone, benzoin ether compounds such as benzoin methyl ether, benzoin compounds such as benzoin, benzyl derivatives such as benzyl dimethyl ketal, 2,4,5-triaryl imidazole dimers such as 2-(o-chlorophenyl)-4,5-diphenyl imidazole dimer, benzimidazoles such as 2-mercaptobenzimidazole, phosphine oxides such as bis(2,4,6-trimethylbenzoyl)phenyl phosphine oxide, acridine derivatives such as 9-phenyl acridine, N-phenyl glycine, N-phenyl glycine derivatives and coumarin-based compounds. In addition, as the photopolymerization initiator (C), there may also be used combination of a thioxanthone-based compound and a tertiary amine compound such as combination of diethyl thioxanthone and (dimethylamino)benzoic acid. Meanwhile, from the viewpoint of enhancing a transparency of the core layer and the cladding layer, among the above compounds, preferred are aromatic ketones and phosphine oxides. These photopolymerization initiators (C) may be used alone or in combination of any two or more thereof.

The amount of the base polymer (A) blended in the resin composition is preferably from 5 to 80% by mass on the basis of a total amount of the components (A) and (B). Whereas, the amount of the photopolymerizable compound (B) blended in the resin composition is preferably from 95 to 20% by mass on the basis of the total amount of the components (A) and (B).

When the components (A) and (B) are blended in amounts of 5% by mass or more and 95% by mass or less, respectively, the resulting resin composition can be readily formed into a film. On the other hand, when the components (A) and (B) are blended in amounts of 80% by mass or less and 20% by mass or more, respectively, the base polymer (A) can be readily cured in an entangled state, so that a capability of forming the core pattern upon producing the optical waveguide is enhanced, and the photopolymerization reaction can fully proceed. From the above viewpoints, the amounts of the components (A) and (B) blended in the resin composition are preferably from 10 to 75% by mass and from 90 to 25% by mass, respectively, and more preferably from 20 to 70% by mass and from 80 to 30% by mass, respectively.

The amount of the photopolymerization initiator (C) blended in the resin composition is preferably from 0.1 to 10 parts by mass on the basis of 100 parts by mass of the total amount of the components (A) and (B). When the amount of the photopolymerization initiator (C) blended is 0.1 part by mass or more, the resulting resin composition exhibits a sufficient photosensitivity. On the other hand, when the amount of the photopolymerization initiator (C) blended is 10 part by mass or less, an inside of the resulting resin composition can undergo a sufficient photocuring without increase in absorption of light on a surface layer of the resin composition upon exposure to light. Further, the resin composition containing the photopolymerization initiator (C) in the above-specified amount can be suitably used for production of the optical waveguide without increase in transmission loss owing to adverse influence of the absorption of light by the polymerization initiator itself. From the above viewpoints, the photopolymerization initiator (C) blended in the resin composition is more preferably from 0.2 to 5 parts by mass.

The resin composition as the cladding layer-forming resin may also contain, if required, so-called additives such as antioxidants, yellowing inhibitors, ultraviolet absorbers, visible light absorbers, colorants, plasticizers, stabilizers and fillers unless the addition thereof gives any adverse influence on the effects of the present invention.

The cladding layer-forming resin film (200 in FIG. 3) can be readily produced by dissolving the resin composition containing the components (A) to (C) in a solvent, applying the resulting coating solution onto the support film 10 and then removing the solvent from the obtained coating film.

The material of the support film 10 used in the production process of the cladding layer-forming resin film 200 is not particularly limited, and the support film may be formed from various materials. From the viewpoints of a good flexibility and a high toughness, the support film 10 may be formed from the same film materials as exemplified above for the substrate 1.

The thickness of the support film 10 may appropriately vary depending upon the flexibility as aimed, and is preferably from 5 to 250 μm. The support film having a thickness of 5 μm or more exhibits a high toughness, whereas the support film having a thickness of 250 μm or less exhibits a sufficient flexibility.

In this case, from the viewpoints of protection of the cladding layer-forming resin film 200 or a good winding property upon winding up the film into a roll, a protective film 11 may be laminated on the cladding layer-forming resin film 200, if required. The protective film may be formed from the same film materials as exemplified for the support film 10, and may be subjected to mold release treatment or antistatic treatment, if required.

The solvent used for producing the cladding layer-forming resin film is not particularly limited as long as it is capable of dissolving the resin composition therein. Examples of the solvent include acetone, methyl ethyl ketone, methyl cellosolve, ethyl cellosolve, toluene, N,N-dimethyl acetamide, propylene glycol monomethyl ether, propylene glycol monomethyl ether acetate, cyclohexanone, N-methyl-2-pyrrolidone, and mixed solvents thereof. The solid concentration in the resin solution is preferably from about 30 to about 80% by mass.

The thickness of the lower cladding layer 2 and the upper cladding layer 9 (hereinafter referred to merely as “cladding layer 2, 9”) after dried is preferably from 5 to 500 μm. The cladding layer 2, 9 having a thickness of 5 μm or more can ensure a sufficient clad thickness required for confinement of light therein, whereas the cladding layer 2, 9 having a thickness of 500 μm or less can be readily controlled to exhibit a uniform thickness. From the above viewpoints, the thickness of the cladding layer 2,9 is more preferably from 10 to 100 μm.

In addition, as to the thickness of the cladding layer 2,9, the thickness of the lower cladding layer 2 that is first formed may be the same as or different from the thickness of the upper layer 9 serving for embedding the core pattern therebeneath. For the purpose of surely embedding the core pattern, it is preferred that the thickness of the upper cladding layer 9 be larger than that of the core layer 3.

### (Core Layer-Forming Resin Film)

Next, the core layer-forming resin film (300 in FIG. 4) used in the present invention is described in detail.

The core layer-forming resin 30 used for forming the core layer-forming resin film 300 may be in the form of a resin composition, preferably a photosensitive resin composition, which is designed such that the resulting core layer 3 has a higher refractive index than that of the cladding layer 2,9, and is capable of producing the core pattern 8 by irradiation with activation light. More specifically, as the core layer-forming resin 30, there is preferably used the same resin composition as used for the cladding layer-forming resin, i.e., such a resin composition containing the components (A), (B) and (C) together with the above optional components, if required.

The core layer-forming resin film 300 can be readily produced by dissolving the resin composition containing the components (A) to (C) in a solvent, applying the resulting coating solution onto the support film 4 and then removing the solvent from the obtained coating film. The solvent is not particularly limited as long as it is capable of dissolving the resin composition therein, and may be the same solvent as exemplified above for production of the cladding layer-forming resin film. The solid concentration in the resin solution is preferably from about 30 to about 80% by mass.

The thickness of the core layer-forming resin film 300 is not particularly limited, and may be controlled such that the thickness of the core layer 3 after dried is usually from 10 to 100 μm. The core layer-forming resin film having a thickness of 10 μm or more in terms of the thickness of the dried core layer 3 has such an advantage that a tolerance for positioning or alignment of the resulting optical waveguide upon coupling with light-receiving and light emitting elements or an optical fiber can be increased. Whereas, the core layer-forming resin film having a thickness of 100 μm or less in terms of the thickness of the dried core layer 3 has such an advantage that an coupling efficiency of the resulting optical waveguide upon coupling with light-receiving and light emitting elements or an optical fiber can be enhanced. From the above viewpoints, the thickness of the core layer-forming resin film 300 in terms of the thickness of the dried core layer 3 is preferably from 30 to 70 μm.

The support film 4 used in the production process of the core layer-forming resin film 300 serves for supporting the core layer-forming resin 30 thereon. The material of the support film 4 is not particularly limited. However, from the viewpoints of easy release or peeling from the core layer-forming resin 30 as well as good heat resistance and solvent resistance, as the material of the support film 4, there may be suitably used polyesters such as polyethylene terephthalate, polypropylene and polyethylene.

The thickness of the support film 4 is preferably from 5 to 50 μm. The support film 4 having a thickness of 5 μm or more has such an advantage that a sufficient strength as required for the support film 4 tends to be readily attained, whereas the support film 4 having a thickness of 50 μm or less has such an advantage that a gap between the support film 4 and a mask used upon forming the core pattern tends to be reduced, resulting in formation of finer core pattern. From the above viewpoints, the thickness of the support film 4 is more preferably from 10 to 40 μm and still more preferably from 15 to 30 μm.

From the viewpoints of protection of the core layer-forming resin film 300 or a good winding property upon winding up the film into a roll, a protective film 11 may be laminated on the core layer-forming resin film 300, if required. The protective film may be formed from the same film materials as exemplified for the support film 4, and may also be subjected to mold release treatment or antistatic treatment, if required.

### (Process for Producing Optical Waveguide)

In the followings, the process for producing the optical waveguide according to the present invention is described in detail (by referring to FIGS. 1 and 2). Meanwhile, in the following example of the production process, there is specifically explained one preferred embodiment of the present invention in which the cladding layer-forming resin film (200 in FIG. 3) and the core layer-forming resin film (300 in FIG. 4) are employed.

First, in the first step, the cladding layer-forming resin film (200 in FIG. 3) constituted of the cladding layer-forming resin 20 and the support film 10 is exposed to light or heat to cure the cladding layer-forming resin 20, thereby forming the lower cladding layer 2 (FIG. 1(a)). In this case, the support film 10 serves as the substrate 1 for the lower cladding layer 2 as shown in FIG. 1(a).

The lower cladding layer 2 preferably has a non-stepped flat surface on its side where the core layer is to be laminated, from the viewpoint of a good adhesion to the below-mentioned core layer. Also, the surface flatness of the lower cladding layer 2 can be ensured by using the cladding layer-forming resin film.

In the case where the protective film 11 is provided on a surface of the cladding layer-forming resin film 200 which is opposite to the support film 10 as shown in FIG. 3, after peeling off the protective film therefrom, the cladding layer-forming resin 20 is cured by exposure to light or heating to thereby form the cladding layer 2. In this case, the cladding layer-forming resin 20 is preferably formed into a film on the support film 10 subjected to adhesion treatment. On the other hand, the protective film 11 is preferably subjected to no adhesion treatment in order to facilitate peeling-off thereof from the cladding layer-forming resin film 200. However, the protective film 11 may be subjected to mold release treatment, if required.

The substrate 1 may be provided separately from the support film 10. In this case, if the protective layer 11 is provided on the cladding layer-forming resin film 200, the protective layer 11 is first peeled off, and then the cladding layer-forming resin film 200 is transferred on the substrate 1 by a lamination method using a roll laminator 5 as shown in FIG. 2(a), followed by peeling off the support film 10 therefrom. Next, the cladding layer-forming resin 20 is cured by exposure to light or heating to form the lower cladding layer 2. In this case, there may also be used such a cladding layer-forming resin film 200 composed of the cladding layer-forming resin 20 solely.

Next, in the second and third steps as described in detail below, the core layer 3 is formed on the lower cladding layer 2. In the second and third steps, the core layer-forming resin film 300 is laminated on the lower cladding layer 2 to form the core layer 3 having a higher refractive index than that of the lower cladding layer 2.

More specifically, in the second step, the core layer-forming resin film 300 is temporarily attached onto the lower cladding layer 2 using the roll laminator 5 to laminate the resin film thereon (FIG. 1(b)). From the viewpoints of a good adhesion and an enhanced follow-up ability, the temporary attachment is preferably carried out while pressure-bonding the core layer-forming resin film 300 onto the lower cladding layer 2. The pressure-bonding may be performed while heating by a laminator having a heated roll. The temperature used upon the lamination is preferably from room temperature (25° C.) to 100° C. When the lamination temperature is room temperature or higher, the adhesion between the lower cladding layer and the core layer is enhanced. In particular, when the lamination temperature is 40° C. or higher, the adhesion therebetween can be further enhanced. Whereas, when the lamination temperature is 100° C. or lower, the core layer is prevented from being fluidized upon the lamination using the roll laminator, thereby forming the core layer having a thickness as desired. From the above viewpoints, the lamination temperature is more preferably from 40° C. to 100° C. The pressure used upon the lamination is preferably from 0.2 to 0.9 MPa, and the lamination velocity is preferably from 0.1 to 3 m/min, though not particularly limited to these conditions.

Next, in the third step, the core layer-forming resin film 300 thus temporarily attached in the above second step is thermocompression-bonded onto the lower cladding layer 2 under reduced pressure (FIG. 1(c)). From the viewpoints of a good adhesion and an enhanced follow-up ability, the thermocompression-bonding in the third step is conducted under reduced pressure. The thermocompression-bonding is preferably conducted under reduced pressure using a flat plate-type laminator 6. Meanwhile, the flat plate-type laminator as used herein means such a laminator including a pair of flat plates between which materials to be laminated are interposed and pressure-bonded to each other by applying a pressure thereto. As the flat plate-type laminator, there may be suitably used, for example, the vacuum pressure laminator as described in the Patent Document 2. The upper limit of the vacuum degree used as a scale of the pressure reduction is preferably 10000 Pa or less and more preferably 1000 Pa or less. The vacuum degree is desirably as low as possible from the viewpoints of a good adhesion and a high follow-up ability. On the other hand, the lower limit of the vacuum degree is about 10 Pa from the viewpoint of a good productivity (time required for vacuum-drawing). The heating temperature used upon the thermocompression-bonding is preferably from 40 to 130° C., and the pressure used upon the thermocompression-bonding is preferably from 0.1 to 1.0 MPa (1 to 10 kgf/cm²), though not particularly limited to these conditions.

The core layer-forming resin film 300 is preferably constituted from the core layer-forming resin 30 and the support film 4 from the viewpoint of a good handing property. The core layer-forming resin film 300 is laminated on the lower cladding layer 2 such that the core layer-forming resin 30 faces to the lower cladding layer 2. Alternatively, the core layer-forming resin film 300 may also be composed of the core layer-forming resin 30 solely.

In the case where the protective film 11 is provided on a surface of the core layer-forming resin film 300 which is opposite to the substrate as shown in FIG. 4, after peeling off the protective film 11 therefrom, the core layer-forming resin film 300 is laminated onto the lower cladding layer 2. In this case, the protective film 11 and the support film 4 are preferably subjected to no adhesion treatment in order to facilitate peeling-off of these films from the core layer-forming resin film 300. However, the protective film 11 and the support film 4 may be subjected to mold release treatment, if required.

Next, in the fourth step, the core layer 3 is exposed to light and then developed to form the core pattern 8 of the optical waveguide (FIGS. 1(d) and 1(e)). More specifically, an activation light is irradiated in an image-like manner onto the core layer 3 through a photomask pattern 7. Examples of a light source for the activation light include conventionally known light sources capable of effectively irradiating ultraviolet light such as a carbon arc lamp, a mercury vapor arc lamp, an ultra-high pressure mercury lamp, a high-pressure mercury lamp and a xenon lamp. Alternatively, as the light source, there may also be used a flood lighting lamp for photograph, a solar lamp, etc., which are capable of effectively irradiating visible light.

Next, the support film 4 still remaining attached onto the core layer-forming resin film 300, if any, is peeled off therefrom, and then the core layer is subjected to wet development, etc., to remove non-exposed portions of the core layer, thereby forming the core pattern 8. In the wet development, the core layer is developed with an organic solvent-type developer suitable for the composition of the film by known methods such as spraying, swinging immersion, brushing and scrapping.

Examples of the organic solvent-type developer include N-methyl pyrrolidone, N,N-dimethyl formamide, N,N-dimethyl acetamide, cyclohexanone, methyl ethyl ketone, methyl isobutyl ketone, γ-butyrolactone, methyl cellosolve, ethyl cellosolve, propylene glycol monomethyl ether and propylene glycol monomethyl ether acetate. These developing methods may be used in combination of any two or more thereof according to the requirements.

Examples of the developing method usable in the present invention include a dipping method, a paddle method, a spray method such as high-pressure spray method, a brushing method and a scrapping method. Among these methods, the high-pressure spray method is most suitable in order to improve a resolution of the core pattern.

After completion of the development, the thus formed core pattern may be subjected to post-treatments, if required, such as heat treatment at a temperature of from about 60 to about 250° C. and exposure to light with an intensity of from about 0.1 to about 1000 mJ/cm² to further cure the core pattern 8.

Thereafter, in the fifth step, the cladding layer-forming resin film 200 is laminated over the core pattern 8 in order to allow the core pattern 8 to be embedded therebeneath, and the cladding layer-forming resin 20 of the cladding layer-forming resin film 200 is cured to form the upper cladding layer 9 (FIG. 1(f)). The cladding layer-forming resin film 200 constituted of the cladding layer-forming resin 20 and the support film 10 is laminated over the core pattern 8 such that the cladding layer-forming resin 20 faces to the core pattern 8. In this case, it is preferred that the thickness of the cladding layer 9 be larger than that of the core layer 3 as described above. The curing of the cladding layer-forming resin 20 may be carried out by exposure to light or heating in the same manner as described above.

As shown in FIG. 4, if the protective film 11 is provided on the cladding layer-forming resin film 200 on the side opposite to the support film 10, after peeling off the protective film 11, the cladding layer-forming resin film 200 is laminated over the core pattern and then cured by exposure to light or heating, thereby forming the cladding layer 9. In this case, it is preferred that the cladding layer-forming resin 20 be formed into a film on the support film 10 subjected to adhesion treatment. On the other hand, it is preferred that the protective film 11 be subjected to no adhesion treatment, in order to facilitate peeling-off of the protective film from the cladding layer-forming resin film 200. However, the protective film may be subjected to mold release treatment, if required.

According to the production process of the present invention, in the step for laminating the core layer 3, the above second step and then the above third step are conducted, whereby the optical waveguide having a uniform core which is free from the conventional problems including formation of thick core and deformation of core such as lack of core as well as attachment of foreign matters thereto (FIGS. 1(f) and 2(g)) can be produced with a good productivity.

The present invention is described in more detail below with reference to the following Examples. However, these examples are only illustrative and not intended to limit the invention thereto.

### Production Example 1

### Production of Core Layer-Forming Resin Film and Cladding Layer-Forming Resin Film

The core layer-forming resin composition and the cladding layer-forming resin composition each having the formulation as shown in Table 1 were prepared. Ethyl cellosolve as a solvent was added to the respective resin compositions in an amount of 40 parts by mass based on a total amount of each resin composition to prepare a core layer-forming resin varnish and a cladding layer-forming resin varnish. Meanwhile, in the formulation shown in Table 1, the amount of each of the base polymer (A) and the photopolymerizable compound (B) blended is represented by “% by mass” based on a total amount of the components (A) and (B), whereas the amount of the photopolymerization initiator blended is represented by the proportion (part(s) by mass) based on 100 parts by mass of the total amount of the components (A) and (B).

TABLE 1

| | | (B) | (C) |
|---|---|---|---|
| | (A) | Photopolymerizable | Photopolymerization |
| Items | Base polymer | compound | initiator |
| Core | “PHENOTOHTO | “A-BPEF”*² | 2,2-bis(2-chlorophenyl)- |
| layer-forming | YP-70”*¹ | (39.8% by mass) | 4,4′,5,5′-tetraphenyl- |
| resin | (20.4% by mass) | | 1,2′-biimidazole*⁵ |
| composition | | | (1 part by mass) |
| | | “EA-1020”*³ | 4,4′-bis(dimethylamino) |
| | | (39.8% by mass) | benzophenone*⁶ |
| | | | (0.5 part by mass) |
| | | | 2-mercapto- |
| | | | benzimidazole*⁷ |
| | | | (0.5 part by mass) |
| Cladding | “PHENOTOHTO | “KRM-2110”*⁴ | “SP-170”*⁸ |
| layer-forming | YP-70”*¹ | (64.3% by mass) | (2 parts by mass) |
| resin | (35.7% by mass) | | |
| composition | | | |

Note
*¹“PHENOTOHTO YP-70”; bisphenol A/bisphenol F copolymer-type phenoxy resin available from Tohto Kasei Co., Ltd.
*²“A-BPEF”; 9,9-bis[4-(2-acryloyloxyethoxy)phenyl]fluorene
*³“EA-1020”; bisphenol A-type epoxy acrylate available from Shin-Nakamura Chemical Co., Ltd.
*⁴“KRM-2110”; alicyclic diepoxy carboxylate available from Shin-Nakamura Chemical Co., Ltd.
*⁵2,2-bis(2-chlorophenyl)-4,4′,5,5′-tetraphenyl-1,2′-biimidazole available from Tokyo Chemical Industry Co., Ltd.
*⁶4,4′-bis(dimethylamino)benzophenone available from Tokyo Chemical Industry Co., Ltd.
*⁷2-mercaptobenzimidazole available from Tokyo Chemical Industry Co., Ltd.
*⁸“SP-170”; triphenyl sulfonium hexafluoroantimonate salt available from Adeka Corporation.

The thus prepared core layer-forming resin varnish and cladding layer-forming resin varnish were respectively applied on a PET film (“COSMOSHINE A1517” (tradename) available from Toyobo Co., Ltd.; thickness: 16 μm) using an applicator (“YBA-4” available from Yoshimitsu Seiki Co., Ltd.) (adhesion-treated surface inside of a roll was used for the cladding layer-forming resin film; non-treated surface outside of a roll was used for the core layer-forming resin film). The thus applied varnishes were dried at 80° C. for 10 min and then at 100° C. for 10 min to remove the solvent therefrom, thereby obtaining a core layer-forming resin film and a cladding layer-forming resin film. The thickness of the respective films is controllable to an optional value between 5 μm and 100 μm by adjusting a gap of the applicator. In Production Example 1, the thicknesses of the core layer, the lower cladding layer and the upper cladding layer were controlled to 40 μm, 20 μm and 70 μm, respectively, in terms of the thickness of each layer after being cured.

### Example 1

### Production of Optical Waveguide

The cladding layer-forming resin film produced in Production Example 1 was irradiated with ultraviolet light (wavelength: 365 nm) with an intensity of 1000 mJ/cm² using an ultraviolet exposure apparatus “MAP-1200” available from Dainippon Screen Manufacturing Co., Ltd., to subject the film to photocuring, thereby forming the lower cladding layer 2 (refer to FIG. 1(a)).

Next, the core layer-forming resin film produced in Production Example 1 was laminated on the thus formed lower cladding layer using a roll laminator “HLM-1500” available from Hitachi Chemical Company, Ltd., under a pressure of 0.4 MPa at a temperature of 50° C. and a laminating speed of 0.2 m/min (refer to FIG. 1(b)).

Next, using a vacuum pressure laminator in the form of a flat plate-type laminator (“MVLP-500” available from Meiki Co., Ltd.), after an inside of the laminator was evacuated (vacuum-drawn) to a pressure of 500 Pa or less, the core layer-forming resin film thus laminated on the lower cladding layer in the above step was subjected to thermocompression-bonding under a pressure of 0.4 MPa at a temperature of 70° C. for a pressing time of 30 s to form a core layer (refer to FIG. 1(c)).

Successively, the thus formed core layer was irradiated with ultraviolet light (wavelength: 365 nm) with an intensity of 1000 mJ/cm² through a photomask (of a negative type) having a width of 40 μm using the ultraviolet exposure apparatus (refer to FIG. 1(d)). Thereafter, the exposed core layer was developed with a mixed solvent containing ethyl cellosolve and N,N-dimethyl acetamide at a mixing mass ratio of 8:2 to form a core pattern (refer to FIG. 1(e)). Then, the mixed solvent as a developer was washed out with methanol and water.

Next, using the vacuum pressure laminator “MVLP-500” available from Meiki Co., Ltd., after an inside of the laminator was evacuated (vacuum-drawn) to a pressure of 500 Pa or less, the cladding layer-forming resin film produced in Production Example 1 was laminated over the core pattern to embed the core pattern therebeneath under a pressure of 0.4 MPa at a temperature of 70° C. for a pressing time of 30 s. The thus laminated resin film was irradiated with ultraviolet light by the same method and under the same conditions as described above and then subjected to heat treatment at 110° C. to form the upper cladding layer 9, thereby producing an optical waveguide (refer to FIG. 1(f)).

Meanwhile, as a result of measuring a refractive index of each of the core layer and the cladding layer using a prism coupler “Model 12010” available from Metricon Corp., it was confirmed that the core layer and the cladding layer had a refractive index of 1.584 and 1.537, respectively, as measured at a wavelength of 850 nm.

Also, it was confirmed that the optical waveguide produced by the above method was free from formation of thick core and deformation of core such as lack of core as well as inclusion of foreign matters therein, and the yield of the 200 optical waveguides each having a length of 10 cm was 80%. Further, as a result of measuring a transmission loss of the optical waveguide using a 855 nm LED “Q81201” available from Advantest Corporation, as a light source, a light-receiving sensor “Q82214” available from Advantest Corporation, an incident fiber “GI-50” (125 multimode fiber; NA=0.20), a light-emitting fiber “SI-114” (125 multimode fiber; NA=0.22), and an incident light having an effective core diameter of 26 μm, it was confirmed that the transmission loss was in the range of from 1.5 to 1.7 dB/cm.

### Production Example 2

### Production of Cladding Layer-Forming Resin Film

The same procedure as in Production Example 1 was repeated except that the cladding layer-forming resin varnish was applied onto a non-treated surface of a PET film (“COSMOSHINE A1517” (tradename) available from Toyobo Co., Ltd.,; thickness: 16 μm) as the support film 10, thereby producing a cladding layer-forming resin film.

### Example 2

### Production of Optical Waveguide

The same procedure as in Example 1 was repeated except that in the step of forming the lower cladding layer 2, the cladding layer-forming resin film 200 produced in Production Example 2 was transferred onto “FR-4” as the substrate 1 by a roll lamination method, and after peeling off the PET film, the resin film was irradiated with ultraviolet light from the side of the cladding layer-forming resin to cure the resin and form the lower cladding layer 2, thereby producing an optical waveguide.

As a result, it was confirmed that the thus produced optical waveguide was free from formation of thick core and deformation of core such as lack of core as well as inclusion of foreign matters therein, and the yield of the 200 optical waveguides each having a length of 10 cm was 90%. Further, as a result of measuring a transmission loss of the optical waveguide using a 855 nm LED “Q81201” available from Advantest Corporation, as a light source, a light-receiving sensor “Q82214” available from Advantest Corporation, an incident fiber “GI-50” (125 multimode fiber; NA=0.20), a light-emitting fiber “SI-114” (125 multimode fiber; NA=0.22), and an incident light having an effective core diameter of 26 μm, it was confirmed that the transmission loss was 1.5 dB/cm.

### Comparative Example 1

### Production of Optical Waveguide

The same procedure as in Example 1 was repeated except that the step of laminating the core layer-forming resin film on the lower cladding layer by using the roll laminator and then the vacuum pressure laminator was replaced with the step of laminating the core layer-forming resin film on the lower cladding layer by using no roll laminator but by using the vacuum pressure laminator under the same conditions as in Example 1, thereby producing an optical waveguide.

As a result, it was confirmed that the thus produced optical waveguide suffered from formation of thick core, lack of the core and inclusion of foreign matters therein, so that the yield of the 200 optical waveguides each having a length of 10 cm was as low as 15%. Further, as a result of measuring a transmission loss of the optical waveguide using a 855 nm LED “Q81201” available from Advantest Corporation, as a light source, a light-receiving sensor “Q82214” available from Advantest Corporation, an incident fiber “GI-50” (125 multimode fiber; NA=0.20), a light-emitting fiber “SI-114” (125 multimode fiber; NA=0.22), and an incident light having an effective core diameter of 26 μm, it was confirmed that the transmission loss was fluctuated over the range of from 1.5 to 4.0 dB/cm which was broader than that in Example 1.

### Comparative Example 2

### Production of Optical Waveguide

The same procedure as in Example 1 was repeated except that the step of laminating the core layer-forming resin film on the lower cladding layer by using the roll laminator and then the vacuum pressure laminator was replaced with the step of laminating the core layer-forming resin film on the lower cladding layer by using the roll laminator under the same conditions as in Example 1 but without conducting the thermocompression-bonding step using the vacuum pressure laminator, thereby producing an optical waveguide.

As a result, it was confirmed that defective peeling of the core occurred owing to poor adhesion thereof, and the yield of the 200 optical waveguides each having a length of 10 cm was as low as 10%. Further, as a result of measuring a transmission loss of the optical waveguide using a 855 nm LED “Q81201” available from Advantest Corporation, as a light source, a light-receiving sensor “Q82214” available from Advantest Corporation, an incident fiber “GI-50” (125 multimode fiber; NA=0.20), a light-emitting fiber “SI-114” (125 multimode fiber; NA=0.22), and an incident light having an effective core diameter of 26 μm, it was confirmed that the transmission loss was fluctuated over the range of from 1.5 to 30 dB/cm which was much broader than that in Example 1.

### INDUSTRIAL APPLICABILITY

In accordance with the present invention, it is possible to produce an optical waveguide having a deformation-free uniform core which undergoes a less deficiency owing to inclusion of foreign matters therein and is excellent in adhesion between a core pattern and a clad, with a good productivity. The optical waveguide produced according to the process of the present invention exhibits excellent light transmission characteristics and, therefore, can be used in various wide applications such as optical interconnection between boards or within the respective boards.

1. A process for producing an optical waveguide, comprising the steps of:
applying a cladding layer-forming resin onto a substrate and curing the resin to form a lower cladding layer;
laminating a core layer-forming resin film on the lower cladding layer to form a core layer;
subjecting the core layer to exposure to light and development to form a core pattern; and
applying a cladding layer-forming resin over the core pattern to embed the core pattern therebeneath, and curing the resin to form an upper cladding layer,
wherein the step of forming the core layer comprises the steps of (1) allowing the core layer-forming resin film to be temporarily attached onto the lower cladding layer using a roll laminator, and (2) thermocompression-bonding the temporarily attached core layer-forming resin film onto the lower cladding layer under a reduced pressure.

2. The process according to claim 1, wherein in the step (1), the core layer-forming resin film is thermocompression-bonded onto the lower cladding layer using a laminator with a heated roll as the roll laminator to temporarily attach the film thereonto.

3. The process according to claim 1, wherein in the step (2), the core layer-forming resin film thus temporarily attached in the step (1) is thermocompression-bonded onto the lower cladding layer under reduced pressure using a flat plate-type laminator.

4. The process according to claim 1, wherein the lower cladding layer has no stepped portion on its surface on which the core layer is to be laminated.

5. The process according to claim 3, wherein the lower cladding layer has no stepped portion on its surface on which the core layer is to be laminated.

6. The process according to claim 2, wherein the lower cladding layer has no stepped portion on its surface on which the core layer is to be laminated.

7. The process according to claim 2, wherein in the step (2), the core layer-forming resin film thus temporarily attached in the step (1) is thermocompression-bonded onto the lower cladding layer under reduced pressure using a flat plate-type laminator.

8. The process according to claim 7, wherein the lower cladding layer has no stepped portion on its surface on which the core layer is to be laminated.
